(19) United States
(12) Patent Application Publication
(10) Pub. No.: US 2025/0220892 A1
(43) Pub. Date: Jul. 3, 2025

(54) VERTICALLY STACKED MEMORY DEVICE AND ELECTRONIC APPARATUS INCLUDING THE SAME

(71) Applicant: Samsung Electronics Co., Ltd., Suwon-si (KR)

(72) Inventors: Sangwook KIM, Suwon-si (KR); Younjin JANG, Suwon-si (KR); Moonil JUNG, Suwon-si (KR); Narae HAN, Suwon-si (KR)

(73) Assignee: Samsung Electronics Co., Ltd., Suwon-si (KR)

(21) Appl. No.: 18/999,144

(22) Filed: Dec. 23, 2024

(30) Foreign Application Priority Data
Jan. 3, 2024 (KR) 10-2024-0000900

(51) Int. Cl. H10B 12/00

(52) U.S. Cl. CPC H10B 12/488; H10B 12/315; H10B 12/482

(57) ABSTRACT

A memory device includes a bit line extending in a first direction, an oxide semiconductor layer extending in a second direction intersecting the first direction and connected to the bit line, the oxide semiconductor layer comprising a source region, a drain region, and a channel region between the source region and the drain region, a capacitor electrically connected to the oxide semiconductor layer, a word line extending to intersect the oxide semiconductor layer in a third direction intersecting the first direction and the second direction, a first insulator on both side surfaces of the source region and the drain region in the third direction, and a second insulator different from the first insulator and on both sides of the channel region in the third direction.

### CROSS-REFERENCE TO RELATED APPLICATION

This application is based on and claims priority under 35 U.S.C. § 119 to Korean Patent Application No. 10-2024-0000900, filed on Jan. 3, 2024, in the Korean Intellectual Property Office, the disclosure of which is incorporated by reference herein in its entirety.

### BACKGROUND

### 1. Field

The disclosure relates to vertically stacked memory devices and electronic apparatuses including the vertically stacked memory device, and more specifically, to vertically stacked memory devices having an oxide semiconductor channel and electronic apparatuses including the vertically stacked memory device.

### 2. Description of the Related Art

A unit memory cell of a typical dynamic random access memory (DRAM) device includes one transistor and one capacitor and may store information by charging or discharging electric charges in or from the capacitor. As electronic products become compact and deliver higher performance, various structures that may increase the integration of memory devices such as DRAM used in electronic products are being proposed to further increase the capacity of memory devices. For example, due to a limit to reducing the area of a unit memory cell, a memory device with a three-dimensional structure in which a plurality of memory cells are stacked vertically on a substrate has been proposed. However, single crystal silicon, which is mainly used as a channel material in typical unit memory cells, requires a high temperature deposition process, making it difficult to stack a plurality of memory cells.

### SUMMARY

Some example embodiments provide vertically stacked memory devices and electronic apparatuses including the vertically stacked memory device.

Some example embodiments provide vertically stacked memory device having an oxide semiconductor channel and an electronic apparatus including the vertically stacked memory device.

Some example embodiments provide vertically stacked memory devices including an oxide semiconductor with relatively low contact resistance between a source region and a drain region and electronic apparatuses including the vertically stacked memory device.

Additional aspects will be set forth in part in the description which follows and, in part, will be apparent from the description, or may be learned by practice of the presented example embodiments of the disclosure.

According to an example embodiment of the disclosure, a memory device includes a plurality of bit lines extending in a first direction, a plurality of oxide semiconductor layers extending in a second direction intersecting the first direction and connected to the plurality of bit lines, respectively, each of the plurality of oxide semiconductor layers including a source region, a drain region, and a channel region between the source region and the drain region, a plurality of capacitors electrically connected to the plurality of oxide semiconductor layers, respectively, a plurality of word lines extending in a third direction to intersect the plurality of oxide semiconductor layers, the third direction intersecting the first direction and the second direction, a first insulator on each of both side surfaces of the source region and the drain region in the third direction, and a second insulator on each of both sides of the channel region in the third direction, the second insulator being different from the first insulator.

The first insulator may include an insulator material that relatively prevents oxygen diffusion, and the second insulator includes an insulator material that relatively assists oxygen diffusion.

For example, the first insulator may include at least one of silicon nitride, silicon oxynitride, or aluminum oxide.

For example, the second insulator may include silicon oxide.

An oxygen content in the channel region may be higher than an oxygen content in the source region and the drain region.

The channel region may face a corresponding word line among the plurality of word lines in the first direction, the source region contacts a corresponding bit line among the plurality of bit lines in the second direction, and the drain region may contact a corresponding capacitor among the capacitors in the second direction.

Each of the plurality of word lines may include a first word line and a second word line arranged apart from each other in the first direction with a corresponding oxide semiconductor layer among the plurality of oxide semiconductor layers therebetween, the first word line and the second word line being parallel to each other and facing each other.

In a cross-section cut through the memory device in a plane perpendicular to the third direction, a group of the plurality of oxide semiconductor layers connected to a corresponding bit line among the plurality of bit lines may be arranged at intervals therebetween in the first direction, and a width of each of the plurality of word lines in the second direction may be less than a width of a corresponding one of the plurality of oxide semiconductor layers in the second direction.

In the cross-section of the memory device cut along the plane perpendicular to the third direction, the first insulator may fill respective spaces on both sides of the plurality of word lines in the second direction.

In the cross-section of the memory device cut along the plane perpendicular to the third direction, the second insulator extends in the second direction and is between two adjacent ones of the plurality of oxide semiconductor layers in the first direction.

The memory device may further include, in the cross-section of the memory device cut along the plane perpendicular to the third direction, a gate insulating film surrounding each of a lower surface and an upper surface of a corresponding one of the plurality of word lines and a second end side surface of the corresponding one of the plurality of word lines in the second direction.

In the cross-section of the memory device cut along the plane perpendicular to the third direction, the gate insulating film may be between the second end side surface of the corresponding one of the plurality of word lines in the second direction and the first insulator, and the first insulator may be in direct contact with a first end side surface of the corresponding one of the plurality of word lines in the second direction.

In a cross-section of the memory device in which the channel region of each of the plurality of oxide semiconductor layers is cut along a plane perpendicular to the second direction, the plurality of word line may extend in the third direction, and the gate insulating film may be in contact with each of the upper surface and the lower surface of a corresponding one of the plurality of word lines and extend in the third direction.

The gate insulating film may include a plurality of gate insulating films, and in the cross-section of the memory device in which the channel region of each of the plurality of oxide semiconductor layers is cut along the plane perpendicular to the second direction, each of the plurality of oxide semiconductor layers may be between two adjacent gate insulating films, that are adjacent to each other in the first direction, from among the plurality of gate insulating films adjacent.

In the cross-section of the memory device in which the channel region of each of the plurality of oxide semiconductor layers is cut along the plane perpendicular to the second direction, the second insulator may be on both sides of a corresponding one of the plurality of oxide semiconductor layers in the third direction, on a same layer as the corresponding one of the plurality of oxide semiconductor layers, and an upper surface and a lower surface of the second insulator may be in contact with the gate insulating film.

In a cross-section of the memory device in which the source region or the drain region of each of the plurality of oxide semiconductor layers is cut along a plane perpendicular to the second direction, the source region or the drain region of each of the plurality of oxide semiconductor layers may be completely surrounded by the first insulator.

The memory device may further include the second insulator spaced apart from the plurality of oxide semiconductor layers and between two adjacent ones of the plurality of oxide semiconductor layers in the first direction, in the cross-section, in the cross-section of the memory device in which the source region or the drain region of the oxide semiconductor layer is cut along the plane perpendicular to the second direction.

In the cross-section of the memory device in which the source region or the drain region of each of the plurality of oxide semiconductor layers is cut along the plane perpendicular to the second direction, a width of the second insulator in the third direction may be equal to a width of a corresponding one of the plurality of oxide semiconductor layers in the third direction.

In the cross-section of the memory device in which the source region or the drain region of each of the plurality of oxide semiconductor layers is cut along the plane perpendicular to the second direction, the second insulator may be completely surrounded by the first insulator.

According to an example embodiment of the disclosure, an electronic apparatus includes a memory device, and a memory controller configured to control the memory device to read data from the memory device or write data to the memory device, wherein the memory device includes a plurality of bit lines extending in a first direction, a plurality of oxide semiconductor layers extending in a second direction intersecting the first direction and connected to the plurality of bit lines, respectively, each of the plurality of oxide semiconductor layers including a source region, a drain region, and a channel region between the source region and the drain region, a plurality of capacitors electrically connected to the plurality of oxide semiconductor layers, respectively, a plurality of word lines extending in a third direction to intersect the plurality of oxide semiconductor layers, the third direction intersecting the first direction and the second direction, a first insulator on each of both sides of the source region and the drain region in the third direction, and a second insulator on each of both sides of the channel region in the third direction, the second insulator being different from the first insulator.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1 is a perspective view illustrating a schematic structure of a vertically stacked memory device according to an example embodiment;

FIG. 2 is a horizontal cross-sectional view schematically illustrating a cross-section around one oxide semiconductor layer, particularly illustrating a cross-sectional configuration along line A-A′ of FIG. 1;

FIG. 3 is a perspective view illustrating a schematic structure of a vertically stacked memory device according to an example embodiment;

FIGS. 4 to 36 illustrate a process of manufacturing the vertically stacked memory device illustrated in FIG. 3, according to an example embodiment;

FIG. 37 illustrates a vertical cross-section of a plurality of memory cells of a vertically stacked memory device manufactured through the process illustrated in FIGS. 4 to 36;

FIG. 38 illustrates another vertical cross-section of a plurality of memory cells of a vertically stacked memory device manufactured through the process illustrated in FIGS. 4 to 36;

FIG. 39 illustrates another vertical cross-section of a plurality of memory cells of a vertically stacked memory device manufactured through the process illustrated in FIGS. 4 to 36;

FIG. 40 is a schematic block diagram of an electronic system including a vertically stacked memory device, according to an example embodiment; and

FIG. 41 is a schematic block diagram of another electronic system including a vertically stacked memory device, according to an example embodiment.

### DETAILED DESCRIPTION

Reference will now be made in detail to some example embodiments, which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a vertically stacked memory device and an electronic apparatus including the vertically stacked memory device will be described in detail with reference to the attached drawings. In the drawings, like reference numerals refer to like elements throughout and sizes of constituent elements may be exaggerated for convenience of explanation and the clarity of the specification. Also, the example embodiments described herein may have different forms and should not be construed as being limited to the descriptions set forth herein.

It will also be understood that when an element is referred to as being “on” or “above” another element, the element may be in direct contact with the other element or other intervening elements may be present. The singular forms include the plural forms unless the context clearly indicates otherwise. It should be understood that, when a part “comprises” or “includes” an element, unless otherwise defined, other elements are not excluded from the part and the part may further include other elements.

The use of the terms “a” and “an” and “the” and similar referents are to be construed to cover both the singular and the plural. The steps of all methods described herein can be performed in any suitable order unless otherwise indicated herein or otherwise clearly contradicted by context, and are not limited to the described order.

Also, in the specification, the term “ . . . units” or “ . . . modules” denote units or modules that process at least one function or operation, and may be realized by hardware, software, or a combination of hardware and software.

Furthermore, the connecting lines, or connectors illustrated in the various figures presented are intended to represent functional relationships and/or physical or logical couplings between the various elements. It should be noted that many alternative or additional functional relationships, physical connections or logical connections may be present in a practical device.

The use of any and all examples, or some language (e.g., “such as”) provided herein, is intended merely to better illuminate the disclosure and does not pose a limitation on the scope of the disclosure unless otherwise claimed.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

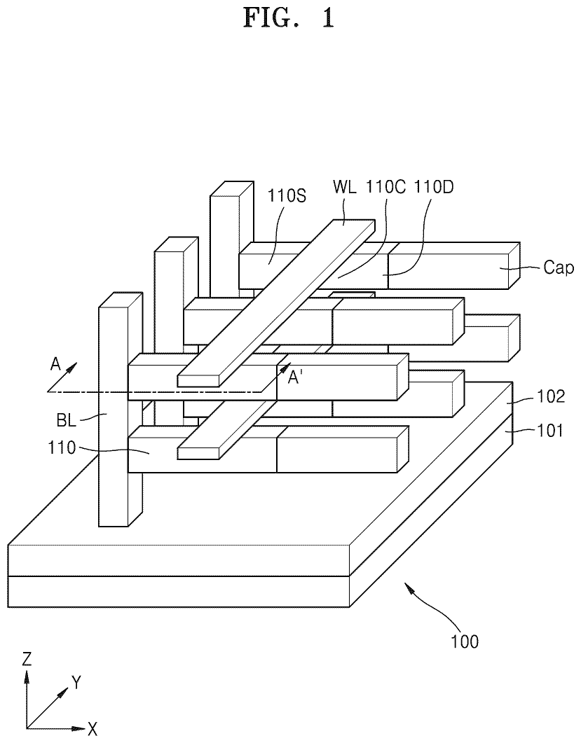

FIG. 1 is a perspective view illustrating a schematic structure of a vertically stacked memory device according to an example embodiment. Referring to FIG. 1, a vertically stacked memory device 100 may include a plurality of bit lines BL extending in a first direction (e.g., Z direction), a plurality of oxide semiconductor layers 110 electrically connected to the plurality of bit lines BL, respectively, and extending in a second direction (e.g., X direction) perpendicular to the first direction, a plurality of capacitors Cap electrically connected to the plurality of oxide semiconductor layers 110, respectively, and a plurality of word lines WL extending in a third direction (e.g., Y direction) perpendicular to the first direction and the second direction and intersecting the plurality of oxide semiconductor layers 110. In FIG. 1, each of the plurality of word lines WL is illustrated as crossing over a corresponding oxide semiconductor layer among the plurality of oxide semiconductor layers 110, but the disclosure is not limited thereto, and the plurality of word lines WL may also cross under a corresponding oxide semiconductor layer.

The vertically stacked memory device 100 may further include a growth substrate 101 and a driving circuit layer 102 provided on the growth substrate 101. The driving circuit layer 102 may include circuits that are connected to an external circuit and perform an input/output operation of receiving data from the outside or outputting data to the outside and an operation of writing data to a capacitor Cap or reading data written to the capacitor Cap.

The plurality of bit lines BL may be provided on the driving circuit layer 102 to be perpendicular to an upper surface of the driving circuit layer 102. In FIG. 1, for convenience, only three bit lines BL arranged in the third direction in a row at intervals therebetween are illustrated. However, in reality, a larger number of bit lines BL may be arranged in two dimensions. For example, the plurality of bit lines BL extending in a vertical direction, that is, in the first direction, may be two-dimensionally arranged on the driving circuit layer 102 at regular intervals in the second direction and the third direction. The plurality of bit lines BL may be arranged parallel to each other.

The plurality of oxide semiconductor layers 110 connected to a corresponding bit line BL among the plurality of bit lines BL may be arranged at intervals therebetween in the first direction. Although only two oxide semiconductor layers 110 are illustrated for one bit line BL in FIG. 1 for convenience, a larger number of oxide semiconductor layers 110 may be arranged at intervals therebetween in the first direction. Within the same layer, the plurality of oxide semiconductor layers 110 may be arranged in parallel to each other at regular intervals in the third direction. The plurality of oxide semiconductor layers 110 arranged on the same layer may each be connected to corresponding different bit lines among the plurality of bit lines BL, respectively. Like the plurality of bit lines BL, the plurality of oxide semiconductor layers 110 may be further arranged at regular intervals in the second direction and the third direction. Therefore, the plurality of oxide semiconductor layers 110 may be three-dimensionally arranged in the first direction, the second direction, and the third direction. Each of the plurality of oxide semiconductor layers 110 may extend in the second direction. A first end of each of the plurality of oxide semiconductor layers 110 may be electrically connected to a corresponding one bit line among the plurality of bit lines BL. A second end of each of the plurality of oxide semiconductor layers 110, which is opposite to the first end in the second direction, may be electrically connected to the capacitor Cap. The thickness of the oxide semiconductor layer 110 in the first direction may be about 20 nm or less.

The oxide semiconductor layer 110 may include an oxide of at least one of indium (In), zinc (Zn), tin (Sn), gallium (Ga), aluminum (Al), silicon (Si), hafnium (Hf), cadmium (Cd), or germanium (Ge). The oxide semiconductor layer 110 may include, for example, an oxide semiconductor material such as zinc indium oxide (ZIO), indium gallium oxide (IGO), or indium gallium zinc oxide (IGZO).

In FIG. 1, the capacitor Cap is illustrated as a block for convenience, but in reality, the capacitor Cap may include a first electrode, a second electrode, and a dielectric layer disposed between the first electrode and the second electrode. The first electrode of the capacitor Cap may be electrically connected to a second end of a corresponding oxide semiconductor layer among the plurality of oxide semiconductor layers 110. Accordingly, one oxide semiconductor layer 110 and one capacitor Cap may be connected to each other on a one-to-one basis. Although not shown, the second electrode of the capacitor Cap may be connected to a ground line of the vertically stacked memory device 100.

The word lines WL may extend in the third direction to cross over the corresponding plurality of oxide semiconductor layers 110. The plurality of word lines WL may be arranged at intervals therebetween in the first direction. In FIG. 1, for convenience, only one word line WL arranged in one layer is illustrated. However, a plurality of word lines WL may be arranged parallel to each other on one layer at intervals in the second direction.

The bit line BL and the word line WL may include a conductive metal or metallic material. For example, the bit line BL and word line WL may include at least one metal or metallic material selected from among polysilicon (p-Si), tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), antimony (Sb), vanadium (V), ruthenium (Ru), platinum (Pt), zinc (Zn), and magnesium (Mg).

Although not illustrated in FIG. 1 for convenience, the vertically stacked memory device 100 may further include an insulator material filled in spaces between the plurality of bit lines BL, between the plurality of oxide semiconductor layers 110, between the plurality of word lines WL, and between the oxide semiconductor layers 110 and the word lines WL corresponding to each other.

In addition, each of the plurality of oxide semiconductor layers 110 may include a channel region 110C facing a corresponding word line WL among the plurality of word lines WL in the first direction, a source region 110S electrically connected to a corresponding bit line BL among the plurality of bit lines BL, and a drain region 110D electrically connected to a corresponding capacitor Cap among the plurality of capacitors Cap. For example, the source region 110S may directly contact a corresponding bit line BL in the second direction, and the drain region 110D may directly contact a corresponding capacitor Cap in the second direction. Accordingly, the channel region 110C may be located between the source region 110S and the drain region 110D.

One oxide semiconductor layer 110 may form one oxide semiconductor transistor together with one word line WL corresponding thereto. The word line WL may act as a gate of the oxide semiconductor transistor. When a gate signal equal to or greater than the threshold voltage is applied to the word line WL, current may flow along the channel region 110C. Then, a bit line BL and a capacitor Cap corresponding to the bit line BL may be electrically connected to each other, so that data may be written to the capacitor Cap or data written in the capacitor Cap may be read.

Accordingly, one oxide semiconductor layer 110 and one capacitor Cap corresponding thereto may form one memory cell. The vertically stacked memory device 100 according to an example embodiment may include a plurality of memory cells arranged two-dimensionally in the second direction and the third direction on one layer. Additionally, the vertically stacked memory device 100 may have a structure in which a plurality of layers including a plurality of two-dimensionally arranged memory cells are stacked in the first direction. Thus, the recording capacity of the vertically stacked memory device 100 may be improved due to the high integration of memory cells.

According to an example embodiment, the oxygen content of the channel region 110C may be different from the oxygen content of the source region 110S and the drain region 110D. In the oxide semiconductor layer 110, carriers (e.g., free electrons) are mainly generated by oxygen vacancies. Accordingly, in order to lower contact resistance, the source region 110S and the drain region 110D may be desired to have a relatively high carrier density, that is, a relatively high density of oxygen vacancies. On the other hand, the channel region 110C may be desired to have a relatively low density of oxygen vacancies to increase the threshold voltage and reduce leakage current. In other words, the oxygen content in the channel region 110C may be higher than the oxygen content in the source region 110S and the drain region 110D.

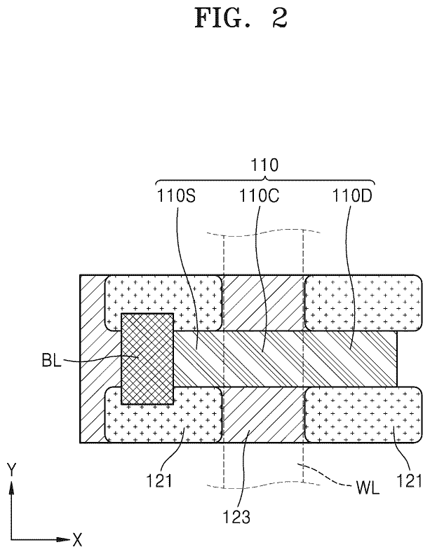

To this end, an insulator to help oxygen diffusion is provided around the channel region 110C in the oxide semiconductor layer 110, and an insulator to block or prevent oxygen diffusion may be provided around the source region 110S and the drain region 110D. FIG. 2 is a horizontal cross-sectional view schematically illustrating a cross-section around one oxide semiconductor layer 110, and in particular, illustrates a cross-sectional configuration along line A-A′ of FIG. 1. In other words, FIG. 2 illustrates an example of a peripheral configuration of one oxide semiconductor layer 110 illustrated in FIG. 1 along a plane perpendicular to the first direction or a plane parallel to the second direction and the third direction.

Referring to FIG. 2, a first insulator 121 may be provided in the third direction, on both side surfaces of the source region 110S in contact with the bit line BL and the drain region 110D in contact with the capacitor Cap. The first insulator 121 may directly contact both side surfaces of the source region 110S and the drain region 110D in the third direction. Additionally, a second insulator 123 that is different from the first insulator 121 may be provided on both sides of the channel region 110C in the third direction, and the channel region 110C faces the word line WL in the first direction. The second insulator 123 may directly contact both side surfaces of the channel region 110C in the third direction. Accordingly, the second insulator 123 may be disposed between the first insulators 121 in the second direction. The first insulator 121 in contact with the source region 110S may extend in the second direction up to the bit line BL. Accordingly, the first insulator 121 may be provided on both side surfaces of the bit line BL in the third direction.

The first insulator 121 may include an insulator material that may block or prevent oxygen diffusion. The second insulator 123 may include an insulator material that may assist oxygen diffusion. For example, the first insulator 121 may include at least one of silicon nitride (SiNₓ), silicon oxynitride (SiONₓ), or aluminum oxide (Al₂O₃). For example, the second insulator 123 may include silicon oxide (SiO₂). Accordingly, the first insulator 121 may block or prevent excess hydrogen or oxygen generated during the manufacturing process of the vertically stacked memory device 100 from diffusing into the source region 110S and the drain region 110D and increasing the contact resistance of the source region 110S and the drain region 110D. The second insulator 123 may efficiently and uniformly provide oxygen to the channel region 110C during oxygen annealing. Accordingly, deterioration of the oxide semiconductor transistor may be reduced or prevented, and quality thereof may be improved.

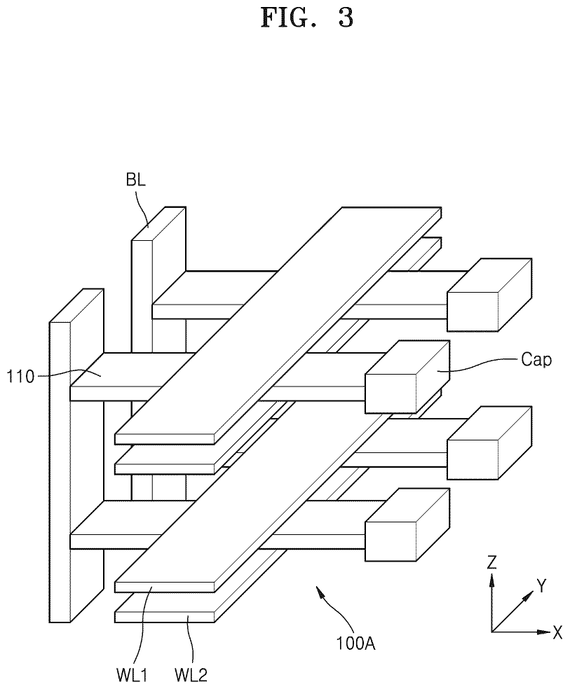

FIG. 3 is a perspective view illustrating a schematic structure of a vertically stacked memory device according to an example embodiment. Referring to FIG. 3, a vertically stacked memory device 100A may have a double gate structure. For example, the vertically stacked memory device 100A may include a first word line WL1 extending in the third direction to cross over a plurality of oxide semiconductor layers 110 arranged in the same layer and a second word line WL2 extending in the third direction to cross under the plurality of oxide semiconductor layers 110 arranged in the same layer. The first word line WL1 and the second word line WL2 may be arranged parallel to each other and to face each other and be spaced apart from each other in the first direction with a corresponding oxide semiconductor layer 110 therebetween. In other words, each of the plurality of word lines WL illustrated in FIG. 1 may be regarded as including the first word line WL1 and the second word line WL2 which are spaced apart from each other in the first direction with a corresponding oxide semiconductor layer among the plurality of oxide semiconductor layers 110 therebetween and are arranged parallel to each other and face each other.

One oxide semiconductor layer 110 may form one oxide semiconductor transistor together with the first word line WL1 and the second word line WL2 which correspond to the one oxide semiconductor layer 110. The operation of one oxide semiconductor transistor may be controlled jointly by the first word line WL1 disposed above the oxide semiconductor layer 110 and the second word line WL2 disposed below the oxide semiconductor layer 110. Accordingly, driving reliability of the oxide semiconductor transistor may be improved. Because other structures of the vertically stacked memory device 100A illustrated in FIG. 3 may be the same as the structures of the vertically stacked memory device 100 illustrated in FIG. 1, detailed descriptions thereof are omitted.

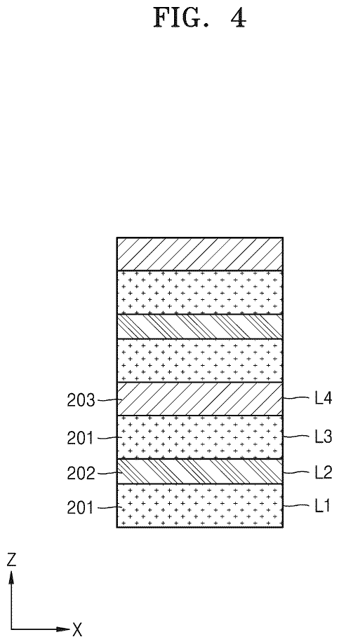

FIGS. 4 to 36 illustrate a process of manufacturing the vertically stacked memory device 100A illustrated in FIG. 3, according to an example embodiment.

Referring to FIG. 4, a first layer L1 including a first insulator 201, a second layer L2 including a sacrificial layer material 202, a third layer L3 including the first insulator 201, and a fourth layer L4 including a second insulator 203 that is different from the first insulator 201 may be sequentially stacked in the first direction. In addition, the first to fourth layers L1, L2, L3, and L4 may be repeatedly stacked in multiple sets. A set of the first to fourth layers L1, L2, L3, and L4 that are sequentially stacked may be a unit stacked structure for forming one layer of memory cells.

The first insulator 201 provided in the first layer L1 and the third layer L3 may function as an insulating film within a layer in which one memory cell is disposed. Additionally, the sacrificial layer material 202 provided in the second layer L2 may act as a sacrificial layer for forming an oxide semiconductor layer. The second insulator 203 provided in the fourth layer L4 may act as an interlayer insulating film between a plurality of memory cells stacked in the first direction. The first insulator 201 may include, for example, at least one of silicon nitride (SiNₓ), silicon oxynitride (SiONₓ), or aluminum oxide (Al₂O₃). The sacrificial layer material 202 may include, for example, polysilicon (p-Si). The second insulator 203 may include, for example, silicon oxide (SiO₂).

In the following manufacturing process, only one unit stacked structure is described for convenience, but the following description may be equally applied to the entire stacked structures in which the first to fourth layers L1, L2, L3, and L4 are repeatedly stacked in multiple sets.

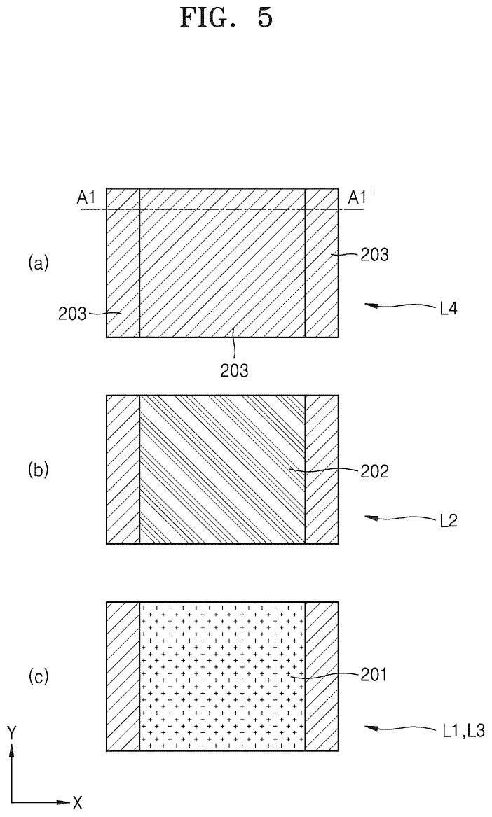

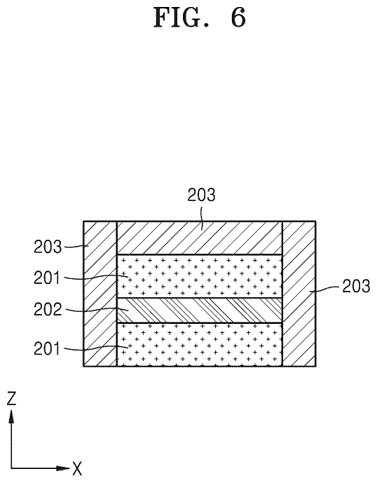

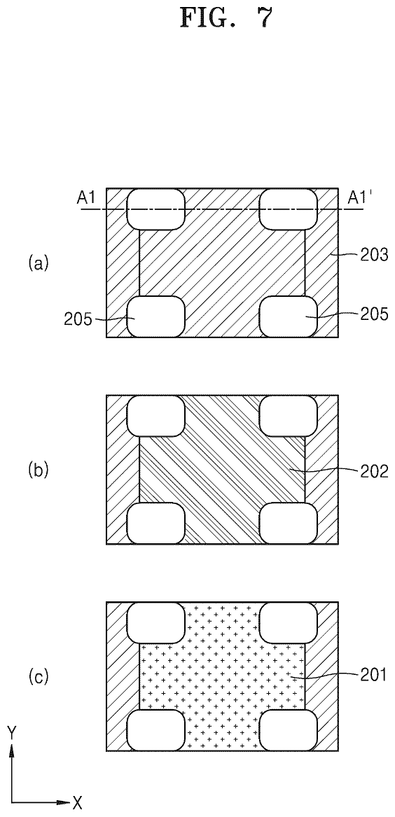

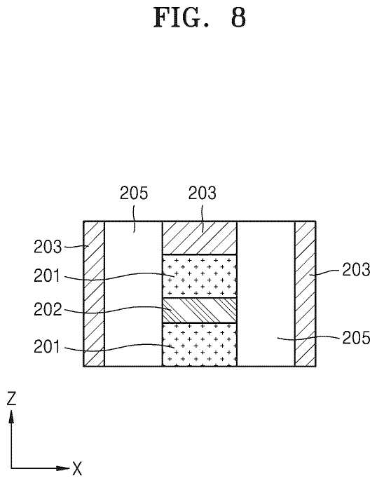

Referring to FIGS. 5 and 6, a first end and a second end of a stacked structure in the second direction may be partially etched, and regions of the etched first end and the etched second end may be filled with the second insulator 203. In FIG. 5, a diagram (a) shows a horizontal cross-section of the fourth layer L4, a diagram (b) shows a horizontal cross-section of the second layer L2, and a diagram (c) shows a horizontal cross-section of each of the first layer L1 and the third layer L3. In other words, FIG. 5 shows cross-sectional views illustrating the cross-sectional shapes of layers including different materials, cut in a plane perpendicular to the first direction. In the entire process, the first layer L1 and the third layer L3 may have substantially the same horizontal cross-sectional shape. FIG. 6 illustrates a vertical cross-section of the unit stack structure cut along line A1-A1′. In other words, FIG. 6 is a cross-sectional view illustrating a cross-sectional shape along a plane perpendicular to the third direction. FIGS. 7, 9, 11, 13, 15, 17, 19, 21, 23, 25, 27, 29, 30, 31, 32, 33, 34, and 36 described below each illustrate the same cross-section as FIG. 5, and FIGS. 8, 10, 12, 14, 16, 18, 20, 22, 24, 26, 28, 30, and 35 each illustrate a cross-section in the same direction as FIG. 6.

Referring to FIGS. 7 and 8, a plurality of vertical holes 205 penetrating the first to fourth layers L1, L2, L3, and L4 may be formed. The plurality of vertical holes 205 may penetrate, for example, regions near four corners of the sacrificial layer material 202.

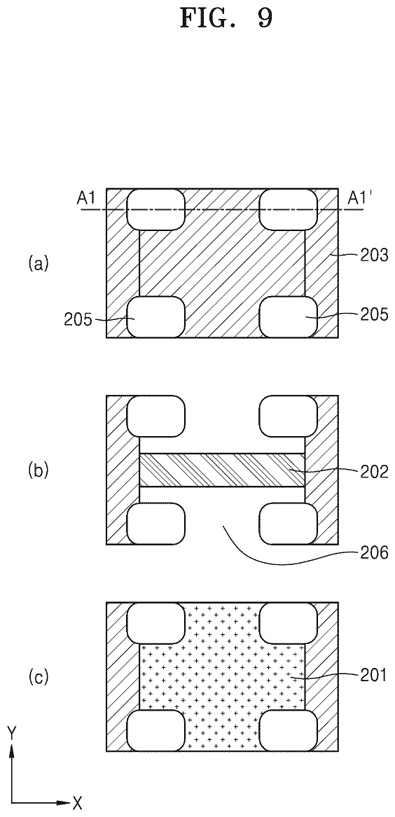

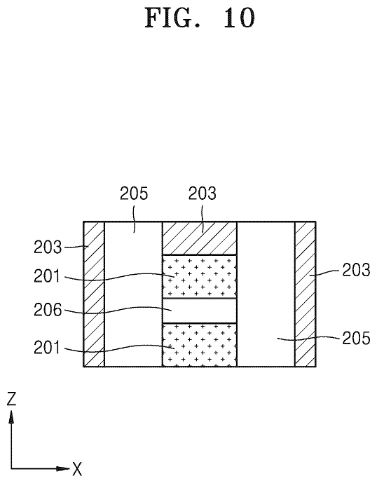

Referring to FIGS. 9 and 10, the sacrificial layer material 202 including polysilicon may be partially removed by supplying an etching solution through the plurality of vertical holes 205. The etching solution may include, for example, a hydrofluoric acid (HF) solution that may dissolve only polysilicon. Then, the sacrificial layer material 202 adjacent to the plurality of vertical holes 205 may be removed, and a space 206 that is empty may be formed in a place from which the sacrificial layer material 202 is removed. For example, the space 206 may be formed at both edges in the third direction, and the sacrificial layer material 202 may partially remain in the second direction in a center in the third direction.

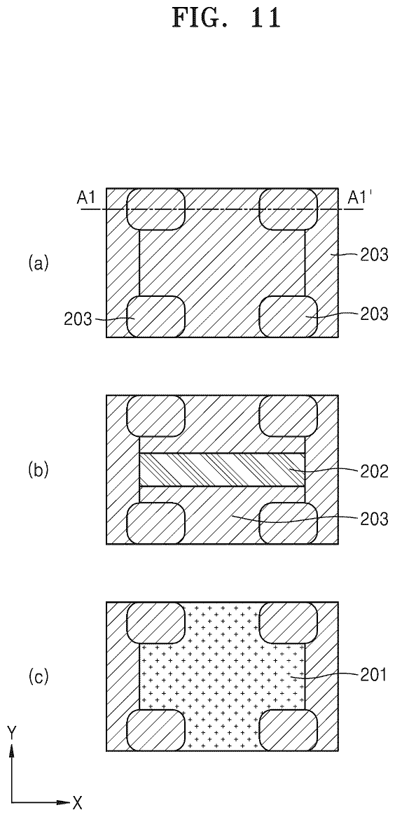

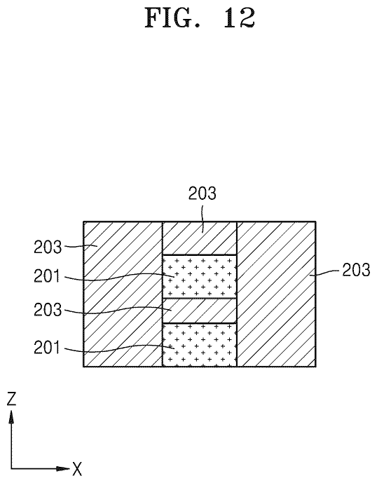

Referring to FIGS. 11 and 12, by supplying the second insulator 203 through the plurality of vertical holes 205, the space 206 in the second layer L2 and the plurality of vertical holes 205 may be filed with the second insulator 203.

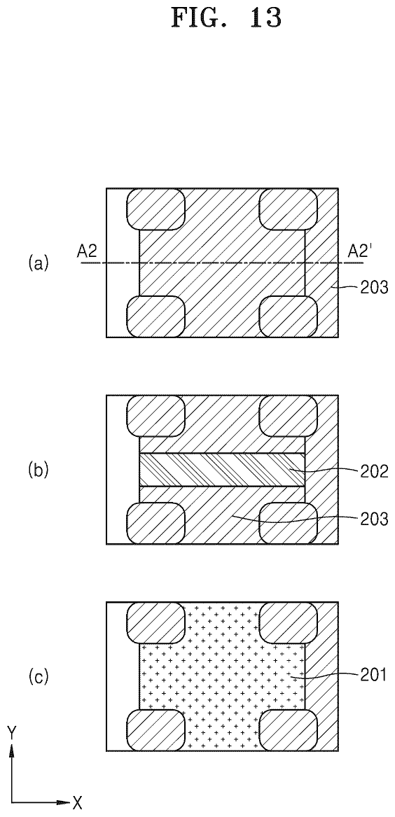

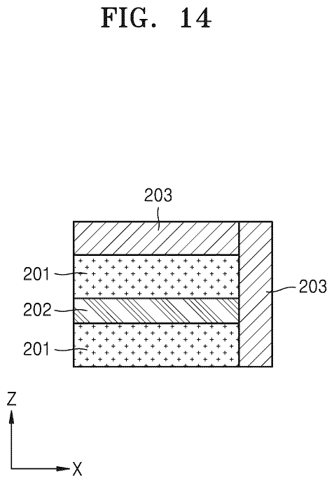

Referring to FIGS. 13 and 14, a first end region of the stacked structure in the second direction may be removed through etching. FIG. 14 illustrates a vertical cross-section of the unit stack structure of FIG. 13 cut along line A2-A2′. In other words, FIG. 14 illustrates a cross-section of the unit stacked structures cut in a center thereof in the third direction, along a plane perpendicular to the third direction. As illustrated in FIG. 14, etching may be performed such that a first end of the first insulator 201 in the second direction in the first layer L1 and the third layer L3 may be exposed to the outside and a first end of the remaining sacrificial layer material 202 in the second layer L2 in the second direction is exposed to the outside. To this end, only the second insulator 203 at the first end of the stacked structure in the second direction may be removed.

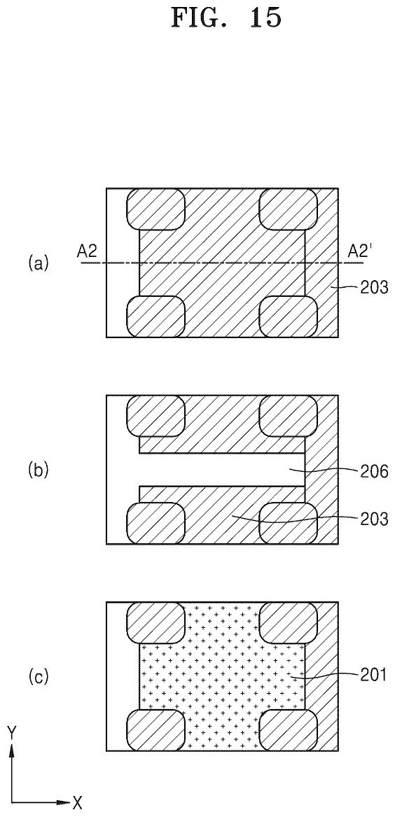

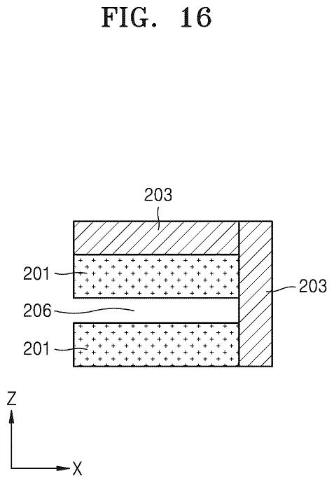

Referring to FIGS. 15 and 16, an etching solution may be supplied through a space formed by removing the second insulator 203 at the first end of the stacked structure in the second direction, then the remaining sacrificial layer material 202 may be completely removed. Then, the empty space 206 may be formed in the second direction in the center portion of the second layer L2 in the third direction.

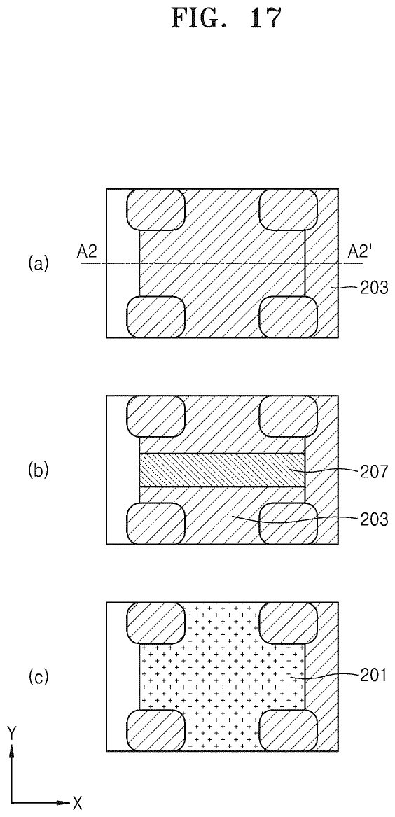

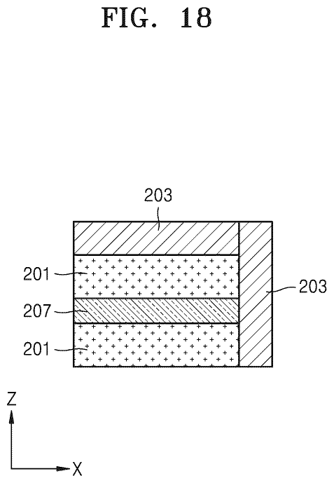

Referring to FIGS. 17 and 18, an oxide semiconductor layer 207 may be formed by depositing an oxide semiconductor in the empty space 206 of the second layer L2. The oxide semiconductor layer 207 may correspond to the oxide semiconductor layer 110 illustrated in FIGS. 1 and 3. For example, the oxide semiconductor layer 207 may be formed by depositing an oxide semiconductor material such as zinc indium oxide (ZIO), indium gallium oxide (IGO), or indium gallium zinc oxide (IGZO). The oxide semiconductor layer 207 may be formed to fill the space 206 and extend, in the second direction, from the center portion of the second layer L2 in the third direction. Before forming the oxide semiconductor layer 207, hydrogen and oxygen in a deposition chamber may be discharged and then the oxide semiconductor layer 207 may be formed so as to ensure relatively high oxygen vacancies and relatively high hydrogen vacancies in the oxide semiconductor material to be deposited, that is, to ensure stoichiometric deficiency of oxygen.

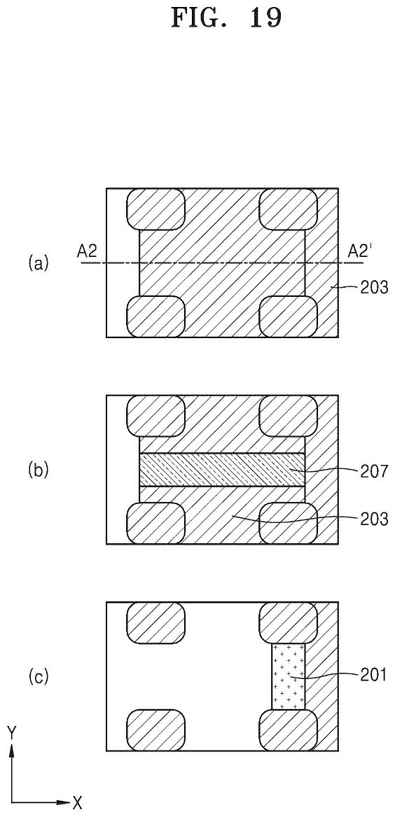

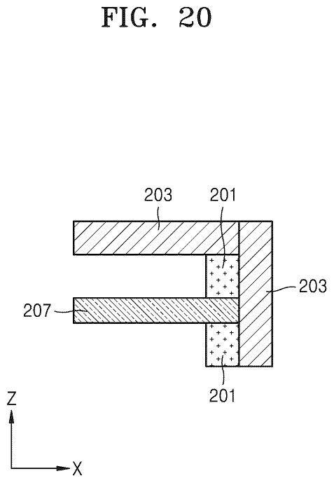

Referring to FIGS. 19 and 20, by supplying an etching solution through the space formed by removing the second insulator 203 at the first end of the stacked structure in the second direction, the first insulator 201 of each of the first layer L1 and the third layer L3 may be removed by etching. While etching the first insulator 201, the etching time may be appropriately adjusted so that the first insulator 201 is not completely removed. For example, the first insulator 201 may partially remain on an upper surface and a lower surface of a second end of the oxide semiconductor layer 207. The remaining areas of an upper surface and a lower surface of the oxide semiconductor layer 207 may be exposed to the outside. Even if the first insulator 201 is removed, the oxide semiconductor layer 207 may be supported by the second insulators 203 on both sides of the oxide semiconductor layer 207 in the third direction.

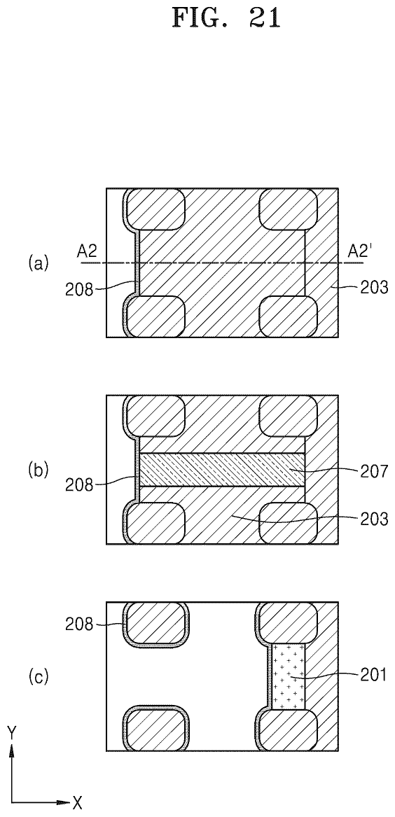

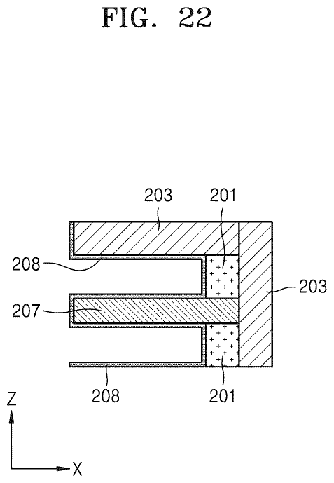

Referring to FIGS. 21 and 22, a gate insulating film 208 may be deposited on exposed surfaces of a first end side of the stacked structure in the second direction. The gate insulating film 208 may be deposited to a certain thickness on the upper surface and the lower surface of the oxide semiconductor layer 207, a surface of the second insulator 203 facing the oxide semiconductor layer 207, and a side surface of the first insulator 201. In this process, the gate insulating film 208 may be partially deposited on a side surface of a first end of the oxide semiconductor layer 207 and a side surface of the second insulator 203. The second insulator 203 of another layer or a substrate is further disposed under the oxide semiconductor layer 207 in FIG. 22. The gate insulating film 208 may also be formed under the oxide semiconductor layer 207. The gate insulating film 208 may be formed so as not to completely fill a space between the oxide semiconductor layer 207 and the second insulator 203.

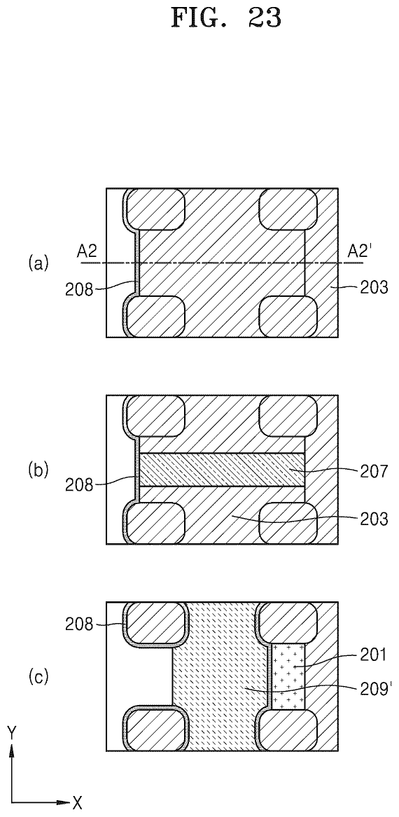

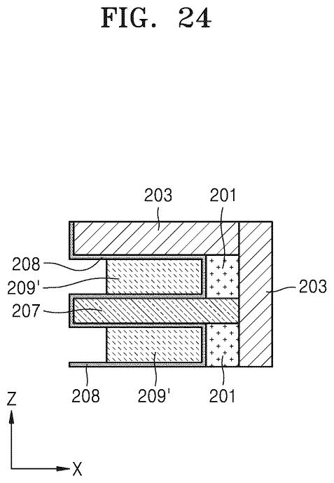

Referring to FIGS. 23 and 24, a dummy word line 209′ may be deposited in the space between the oxide semiconductor layer 207 and the second insulator 203 that is not completely filled with the gate insulating film 208. A lower surface, an upper surface, and a second end side surface of the dummy word line′ 209 formed as above may be surrounded by the gate insulating film 208. Two dummy word lines 209′ facing the lower surface and the upper surface of the oxide semiconductor layer 207, respectively, may be formed. When forming the dummy word lines 209′, the dummy word lines 209′ may be formed to correspond only to partial regions of the lower surface and the upper surface of the oxide semiconductor layer 207. Accordingly, the oxide semiconductor layer 207 may protrude further than the dummy word line 209′ toward the first end thereof in the second direction, and a small space may remain in the second direction between a first end of the dummy word line 209′ and a corresponding end of the gate insulating film 208.

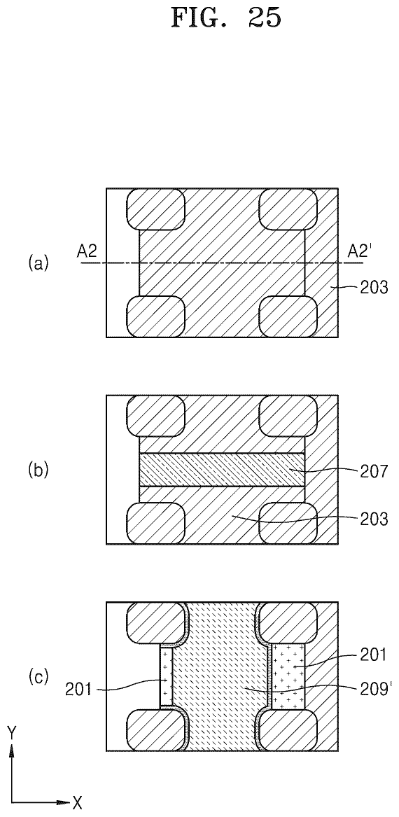

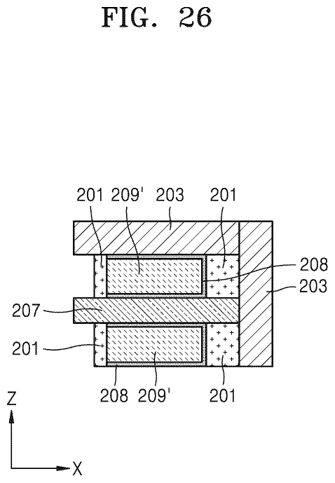

Referring to FIGS. 25 and 26, an undesirable portion of the gate insulating film 208 may be removed. For example, the gate insulating film 208 formed on the side surface of the first end of the oxide semiconductor layer 207 and the side surface of the second insulator 203 may be removed. Additionally, the gate insulating film 208 formed between the oxide semiconductor layer 207 and the second insulator 203 and protruding further than the first end of the dummy word line 209′ may be removed. In other words, the gate insulating film 208 that is not in direct contact with the dummy word line 209 may be removed.

Then, the first insulator 201 may be formed in a space between the oxide semiconductor layer 207 and the second insulator 203 to be in contact with the side surface of the first end of the dummy word line 209′. The first insulator 201 may extend in the first direction between the oxide semiconductor layer 207 and the second insulator 203 so as to contact the gate insulating film 208, a surface of the oxide semiconductor layer 207, and the surface of the second insulator 203. Accordingly, all surfaces of the dummy word line 209′ may be surrounded by an insulating film. For example, the gate insulating film 208 may be in contact with the lower surface, the upper surface, and the second end side surface of the dummy word line 209′, and the first insulator 201 may be in contact with the first end side surface of the dummy word line 209′.

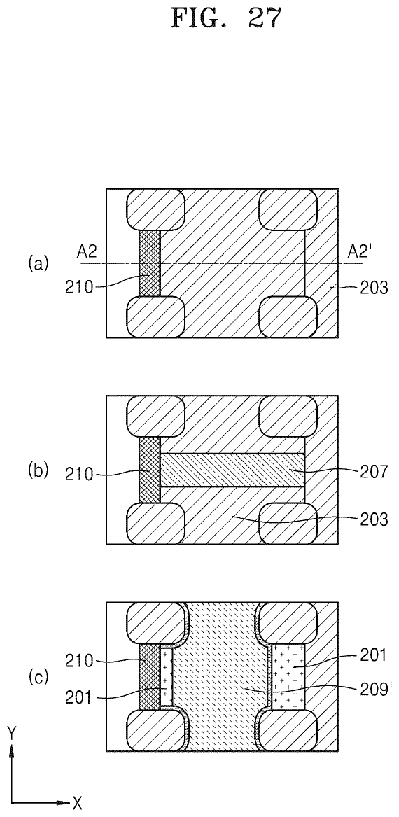

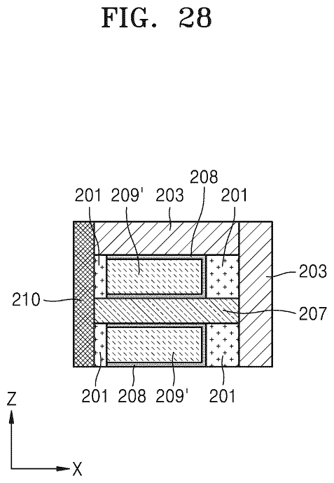

Referring to FIGS. 27 and 28, a bit line 210 may be formed through the first to fourth layers L1, L2, L3, and L4 to contact the first end of the oxide semiconductor layer 207. For example, the bit line 210 may be formed by forming a hole through a center of the stacked structure in the third direction near the first end of the stacked structure, and then filling the hole with a conductive material. The bit line 210 may correspond to the bit line BL illustrated in FIGS. 1 and 3. The bit line 210 may be formed to contact the first end of the oxide semiconductor layer 207. Additionally, the bit line 210 may be formed to contact the first insulator 201 formed on the side surface of the first end of the dummy word line 209′. Accordingly, the dummy word line 209′ and the bit line 210 may be electrically separated from each other by the first insulator 201.

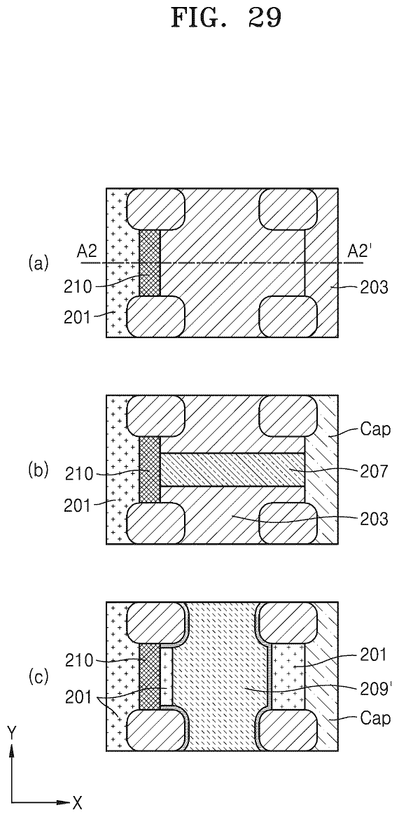

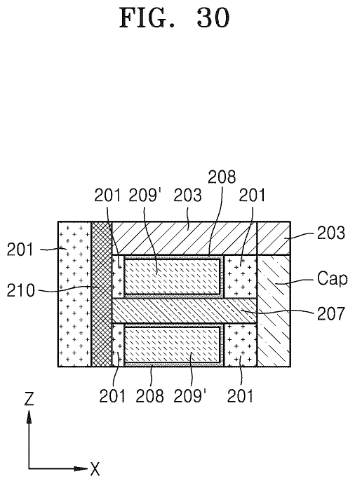

Referring to FIGS. 29 and 30, a second end of the stacked structure may be partially etched in the second direction and removed, and a capacitor Cap may be further formed to electrically contact the second end of the oxide semiconductor layer 207. In FIGS. 29 and 30, the capacitor Cap is simply shown as one block, but the capacitor Cap may include a first electrode, a second electrode, and a dielectric layer disposed between the first electrode and the second electrode. Because the process of forming the capacitor Cap is not a major feature in the disclosure and well-known in the art, detailed description of the process of forming the capacitor Cap will be omitted.

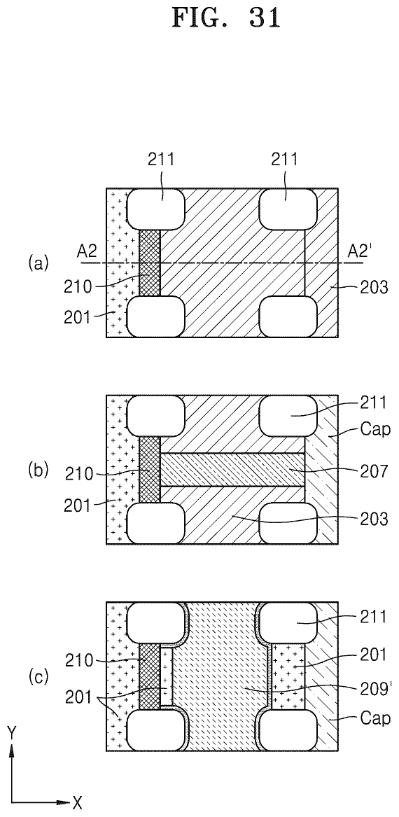

Referring to FIG. 31, a plurality of vertical holes 211 penetrating the first to fourth layers L1, L2, L3, and L4 may be formed again. For example, the plurality of vertical holes 211 may be formed to pass through regions near four corners of the dummy word line 209′.

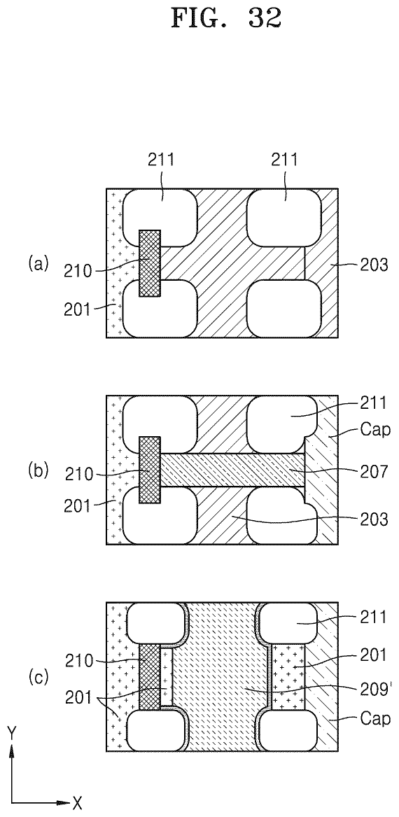

Referring to FIG. 32, the size of the plurality of vertical holes 211 may be increased by further etching the second insulator 203 within the plurality of vertical holes 211. For example, the second insulator 203 in the plurality of vertical holes 211 may be etched until a side surface of the oxide semiconductor layer 207 of the second layer L2 in the third direction is exposed. Accordingly, both side surfaces, in the third direction, of the first end of the second end of the oxide semiconductor layer 207 in the second direction may be exposed. However, both side surfaces, in the third direction, of the oxide semiconductor layer 207 at a center portion thereof in the second direction may still be in contact with the second insulator 203.

The size of the plurality of vertical holes 211 may be relatively wide only in the second layer L2 and the fourth layer L4 where the second insulator 203 is disposed, and the size thereof may be constant in the first layer L1 and the third layer L3 that do not have the second insulator 203. Because only the second insulator 203 within the plurality of vertical holes 211 is selectively removed, the bit line 210 may protrude in the third direction within the widened vertical hole 211 in the first layer L1 and the third layer L3.

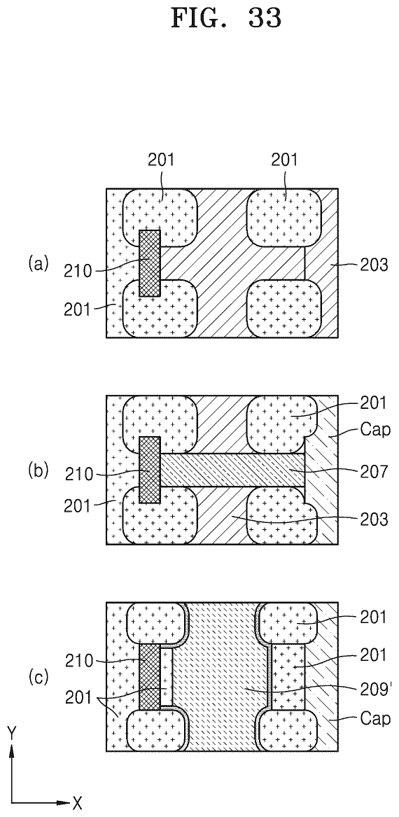

Referring to FIG. 33, the plurality of vertical holes 211 may be completely filled with the first insulator 201. Then, both side surfaces, in the third direction, of the first end and the second end of the oxide semiconductor layer 207 in the second direction may be in contact with the first insulator 201. Because the first insulator 201 is also formed in the first layer L1 and the third layer L3 at positions corresponding to the first end and the second end of the oxide semiconductor layer 207 in the second direction, all surfaces of the oxide semiconductor layer 207 along the perimeter of the first end and the second end of the oxide semiconductor layer 207 in the second direction may be in contact with the first insulator 201. Accordingly, the first end and the second end of the oxide semiconductor layer 207 in the second direction may be completely surrounded by the first insulator 201. Both side surfaces, in the third direction, of the center portion of the oxide semiconductor layer 207 in the second direction may be in contact with the second insulator 203. Accordingly, the second insulator 203 may be positioned between the first insulators 201 in the second direction on both side surfaces of the oxide semiconductor layer 207 in the third direction.

Additionally, both ends of the bit line 210 in the third direction may be completely surrounded by the first insulator 201. In the fourth layer L4, two surfaces of the bit line 210 facing each other in the second direction may contact different insulators. For example, the bit line 210 may include a first surface that contacts the first insulator 201 and a second surface that contacts the second insulator 203 in the fourth layer L4 and is opposite the first surface in the second direction.

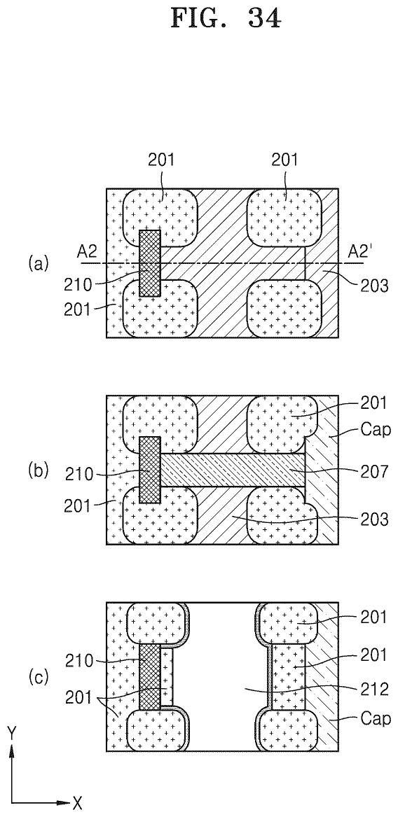

Referring to FIG. 34, the dummy word line 209′ may be selectively removed by providing an etchant through a side surface of the stacked structure in the third direction. Then, the dummy word line 209′ may be removed and an empty space 212 may be formed in the place of the dummy word line 209′.

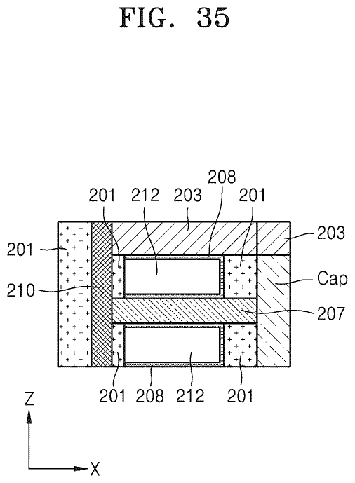

FIG. 35 illustrates a vertical cross-section of a unit stack structure of FIG. 34 cut along line A2-A2′. Referring to FIG. 35, an empty space 212 may be formed in each of regions corresponding to the lower surface and the upper surface of the oxide semiconductor layer 207 in the first direction. For example, the empty space 212 surrounded by the gate insulating film 208 and the first insulator 201 may be formed on each of the lower surface and the upper surface of the oxide semiconductor layer 207.

Afterwards, annealing may be performed in an oxygen (O₂) atmosphere. Then, oxygen may be supplied into the stacked structure through the empty space 212. The second insulator 203 and the gate insulating film 208 may include an insulator material that may assist oxygen diffusion such as silicon oxide (SiO₂). Accordingly, oxygen may diffuse through the gate insulating film 208 and the second insulator 203 within the empty space 212. Oxygen diffused through the gate insulating layer 208 and the second insulator 203 may be injected into the center portion of the oxide semiconductor layer 207 in the second direction. Accordingly, the oxygen content may increase and oxygen vacancies may decrease in the center portion of the oxide semiconductor layer 207 in the second direction. The center portion of the oxide semiconductor layer 207 in the second direction may be a channel region.

The first end and the second end of the oxide semiconductor layer 207 in the second direction may be surrounded by the first insulator 201. The first insulator 201 may include an insulator material that may block or prevent oxygen diffusion, such as silicon nitride (SiNₓ), silicon oxynitride (SiONₓ), or aluminum oxide (Al₂O₃). Therefore, compared to the case of the second insulator 203, relatively less oxygen may be injected into the first end and the second end of the oxide semiconductor layer 207 in the second direction, through the first insulator 201, and oxygen vacancies within the first end and the second end of the oxide semiconductor layer 207 in the second direction may not decrease (e.g., may be relatively high). In other words, the oxygen content in the center portion of the oxide semiconductor layer 207 in the second direction may be higher than the oxygen content in the first end and the second end of the oxide semiconductor layer 207 in the second direction, and the density of oxygen vacancies in the center portion of the oxide semiconductor layer 207 in the second direction may be lower than the density of oxygen vacancies in the first end and the second end of the oxide semiconductor layer 207 in the second direction. The first end and the second end of the oxide semiconductor layer 207 in the second direction may be a source region and a drain region, respectively.

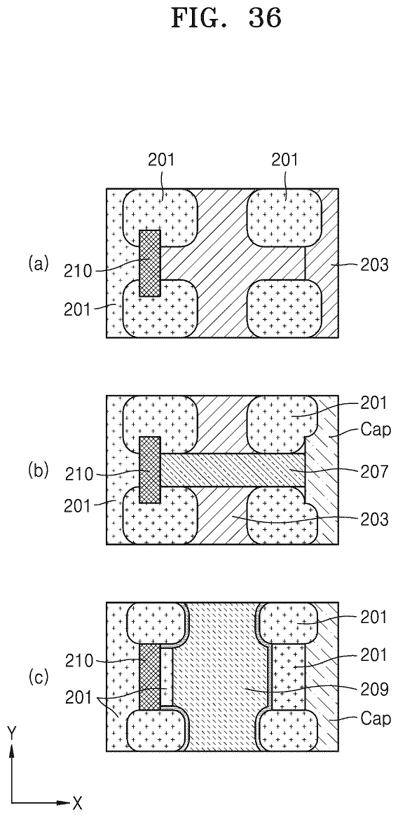

Lastly, referring to FIG. 36, the word line 209 may be formed by depositing a conductive material again inside the empty space 212. The location and shape of the word line 209 may be the same as the dummy word line 209′ described above. Meanwhile, the dummy word line 209′ and the word line 209 may be formed of the same material or may be formed of different materials. For example, the dummy word line 209′ may include a material that may be easily removed in the process illustrated in FIGS. 34 and 35, and need not necessarily be conductive.

In the description with reference to FIGS. 29 to 36 described above, the capacitor Cap is formed first and then the processes illustrated in FIGS. 31 to 36 is performed. However, the disclosure is not necessarily limited thereto, and the capacitor Cap may also be formed last. For example, after first performing the processes illustrated in FIGS. 31 to 36, the capacitor Cap may be formed as illustrated in FIGS. 29 to 30.

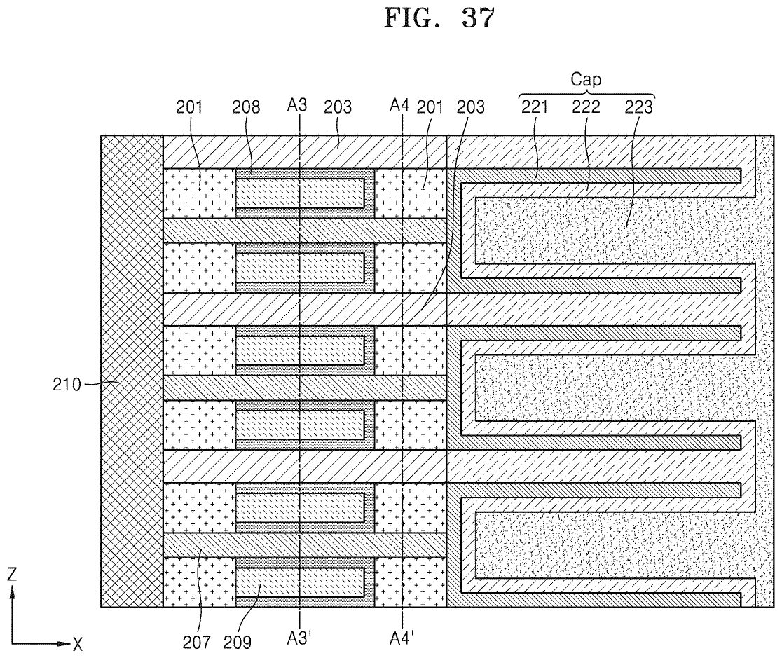

FIG. 37 illustrates a vertical cross-section of a plurality of memory cells of a vertically stacked memory device manufactured through the processes illustrated in FIGS. 4 to 36. For example, FIG. 37 illustrates an example of a cross-section at the same position as that in FIG. 35. Referring to FIG. 37, in a cross-section of the oxide semiconductor layer 207 cut along a plane perpendicular to the third direction, a plurality of second insulators 203 may be provided to extend in the second direction and be spaced apart from each other in the first direction. One memory cell may be provided between two adjacent second insulators 203 in the first direction. A plurality of memory cells and a plurality of second insulators 203 may be repeatedly stacked in the first direction. In a memory cell, an oxide semiconductor layer 207, two word lines 209 disposed on the upper surface and the lower surface of the oxide semiconductor layer 207, respectively, and a gate insulating film 208 surrounding each word line 209 may form an oxide semiconductor transistor. The word line 209 facing the upper surface of the oxide semiconductor layer 207 may correspond to the first word line WL1 of FIG. 3, and the word line 209 facing the lower surface of the oxide semiconductor layer 207 may correspond to the second word line WL2 of FIG. 3. Accordingly, a plurality of oxide semiconductor transistors may be stacked at intervals in the first direction. The second insulator 203 may be provided as an interlayer insulating film between two adjacent oxide semiconductor layers 207 in the first direction or between two adjacent oxide semiconductor transistors in the first direction.

The bit line 210 extending in the first direction may contact the first end of the oxide semiconductor layer 207 in the second direction. The bit line 210 may contact all of the plurality of oxide semiconductor layers 207 stacked in the first direction.

The capacitor Cap may contact the second end of the oxide semiconductor layer 207 in the second direction. The capacitor Cap may include a first electrode 221 electrically connected to the second end of the oxide semiconductor layer 207, a second electrode 223 disposed facing the first electrode 221, and a dielectric layer 222 disposed between the first electrode 221 and the second electrode 223. To increase capacitance, the first electrode 221 may be bent twice, and both ends of the first electrode 221 may be extended in the second direction. The second electrode 223 may be provided in a groove between the first electrodes 221 formed by bending.

A plurality of capacitors Cap may be stacked at intervals in the first direction. One oxide semiconductor transistor and one capacitor Cap adjacent to each other in the second direction may form a memory cell. Accordingly, a plurality of memory cells may be stacked at intervals in the first direction.

The width of the word line 209 and the width of the gate insulating film 208 in the second direction may be less than the width of the oxide semiconductor layer 207 in the second direction. The first insulator 201 may be disposed to fill a space between the oxide semiconductor layer 207, the word line 209, the bit line 210, and the second insulator 203 and between the oxide semiconductor layer 207, the word line 209, the capacitor Cap, and the second insulator 203. In other words, the first insulator 201 may be provided to fill respective spaces on both sides of the plurality of word lines 209 in the second direction.

The gate insulating film 208 may be provided to surround the lower surface and the upper surface of each word line 209 and the second end side surface of each word line 209 in the second direction. Accordingly, the gate insulating film 208 may be between the second end side surface of each word line 209 and the first insulator 201 in the second direction. There is no gate insulating film 208 on the first end side surface of each word line 209 in the second direction. Accordingly, the first insulator 201 may directly contact the first end side surface of each word line 209 in the second direction.

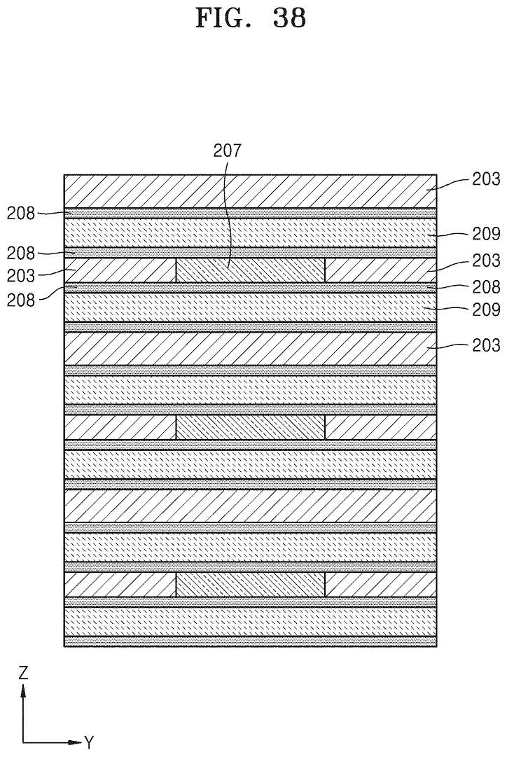

FIG. 38 illustrates another vertical cross-section of a plurality of memory cells of a vertically stacked memory device manufactured through the process illustrated in FIGS. 4 to 36. In particular, FIG. 38 illustrates a vertical cross-section of the vertically stacked memory device illustrated in FIG. 37 along line A3-A3′. In other words, FIG. 38 shows a cross-section cut along a plane perpendicular to the second direction near the channel region, which is the center portion of the oxide semiconductor layer 207. Referring to FIG. 38, the word line 209 may extend in the third direction. Additionally, the gate insulating film 208 may extend in the third direction in contact with each of the upper surface and the lower surface of the word line 209.

The oxide semiconductor layer 207 may be disposed between two word lines 209 adjacent to each other in the first direction or between two gate insulating films 208 adjacent to each other in the first direction. The width of the oxide semiconductor layer 207 in the third direction may be less than the width of the word line 209 in the third direction. The second insulator 203 may be further provided on both sides of each oxide semiconductor layer 207 in the third direction. In particular, the second insulator 203 may be provided on each of both sides of the channel region of each corresponding oxide semiconductor layer 207 in the third direction, on the same layer as the corresponding oxide semiconductor layer 207. Additionally, the second insulator 203 may be disposed between two adjacent gate insulating films 208 in the first direction, and each of the upper surface and the lower surface of the second insulator 203 may be in contact with the gate insulating film 208.

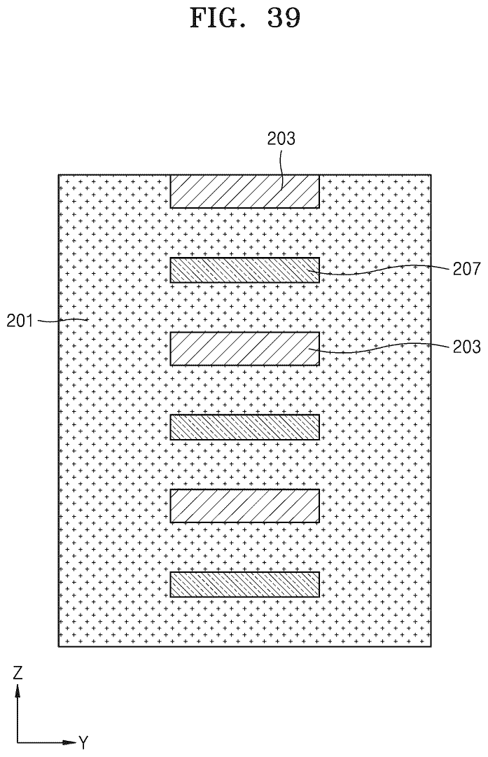

FIG. 39 illustrates another vertical cross-section of a plurality of memory cells of a vertically stacked memory device manufactured through the process illustrated in FIGS. 4 to 36. In particular, FIG. 39 illustrates a vertical cross-section of the vertically stacked memory device illustrated in FIG. 37 along line A4-A4′. In other words, FIG. 39 shows a cross-section cut along a plane perpendicular to the second direction near the drain region, which is the second end of the oxide semiconductor layer 207, in the second direction. Referring to FIG. 39, the drain region of the oxide semiconductor layer 207 may be completely surrounded by the first insulator 201. As previously described, because the first insulator 201 hardly transmits oxygen, oxygen may hardly diffuse into the drain region of the oxide semiconductor layer 207 surrounded by the first insulator 201 during the oxygen annealing process.

The second insulator 203 may be provided between two adjacent oxide semiconductor layers 207 in the first direction and spaced apart from the oxide semiconductor layer 207. The second insulator 203 may face the oxide semiconductor layer 207 in the first direction. In a cross-section near the drain region of the oxide semiconductor layer 207, the width of the second insulator 203 in the third direction may be substantially equal to the width of the oxide semiconductor layer 207 in the third direction. Additionally, the first insulator 201 may be between the second insulator 203 and the oxide semiconductor layer 207 in the first direction. Accordingly, the second insulator 203 may be completely surrounded by the first insulator 201 like the drain region of the oxide semiconductor layer 207.

Meanwhile, the cross-sectional view near the source region of the oxide semiconductor layer 207 may also be the same as that in FIG. 39. Accordingly, the source region of the oxide semiconductor layer 207 may be completely surrounded by the first insulator 201.

As described above, a vertically stacked memory device according to an example embodiment may include an oxide semiconductor that may be deposited at a relatively low temperature, as a channel material for an oxide semiconductor transistor. Therefore, a plurality of memory cells may be stacked vertically without damage due to high temperature. In addition, according to an example embodiment, an insulator which may help oxygen diffusion may be disposed around a channel of an oxide semiconductor layer, and an insulator which may block or prevent oxygen diffusion may be disposed around a source region and a drain region of the oxide semiconductor layer, and thus, leakage current of the oxide semiconductor transistor and contact resistance of the source region and the drain region may be reduced. Therefore, the quality of the vertically stacked memory device may be improved in terms of driving speed, reliability, and power consumption.

The vertically stacked memory device described above may be applied to various electronic systems that store information or output and use the stored information.

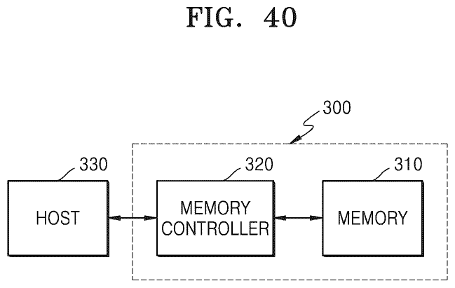

FIG. 40 is a schematic block diagram of an electronic system including a memory device, according to an example embodiment. Referring to FIG. 40, an electronic system 300 according to an example embodiment includes a memory device 310 and a memory controller 320. The memory controller 320 may control the memory device 310 to read data from the memory device 310 and/or write data to the memory device 310, in response to a request by a host 330. The memory device 310 may include the memory device 100 according to the example embodiment described above.

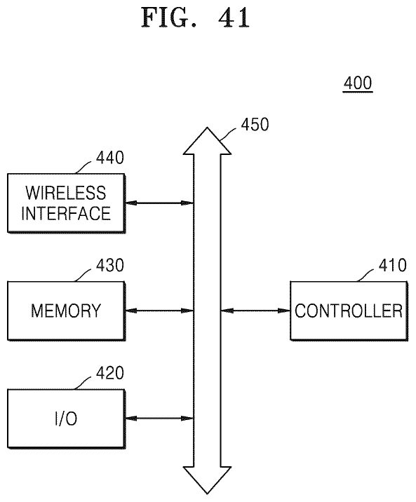

FIG. 41 is a schematic block diagram of another electronic system including a memory device, according to an example embodiment. Referring to FIG. 41, an electronic system 400 may configure a wireless communication device or a device capable of transmitting and/or receiving information in a wireless environment. The electronic system 400 includes a controller 410, an input/output device (I/O) 420, a memory device 430, and a wireless interface 440, which are respectively connected to one another through a bus 450.

The controller 410 may include at least one of a microprocessor, a digital signal processor, or a processing device similar thereto. The input/output device 420 may include at least one of a keypad, a keyboard, or a display. The memory device 430 may be used to store commands executed by the controller 410. For example, the memory device 430 may be used to store user data. The electronic system 400 may use the wireless interface 440 to transmit/receive data over a wireless communication network. The wireless interface 440 may include an antenna and/or a wireless transceiver. The memory device 430 may include the memory device 100 according to the example embodiment described above.

The vertically stacked memory device and an electronic apparatus including the vertically stacked memory device are described above according to the embodiments illustrated in the drawings. However, the descriptions are only examples, and one of ordinary skill in the art may understand that various modifications and equivalent embodiments are possible from the descriptions. The disclosed embodiments should be considered in a descriptive sense only and not for purposes of limitation. The scope of the disclosure is defined not by the detailed description of the disclosure but by the appended claims, and all differences within the scope will be construed as being included in the disclosure.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that the example embodiments described herein should be considered in a descriptive sense only and not for purposes of limitation. Descriptions of features or aspects within one example embodiment should typically be considered as available for other similar features or aspects in another example embodiments. While some embodiments have been described with reference to the figures, it will be understood by those of ordinary skill in the art that various changes in form and details may be made therein without departing from the spirit and scope as defined by the following claims.

What is claimed is:

1. A memory device comprising:
a plurality of bit lines extending in a first direction;
a plurality of oxide semiconductor layers extending in a second direction intersecting the first direction and connected to the plurality of bit lines, each of the plurality of oxide semiconductor layers comprising a source region, a drain region, and a channel region between the source region and the drain region;
a plurality of capacitors electrically connected to the plurality of oxide semiconductor layers, respectively;
a plurality of word lines extending in a third direction to intersect the plurality of oxide semiconductor layers, the third direction intersecting the first direction and the second direction,
a first insulator on each of both side surfaces of the source region and the drain region in the third direction; and
a second insulator on each of both sides of the channel region in the third direction, the second insulator being different from the first insulator.

2. The memory device of claim 1, wherein the first insulator comprises an insulator material that relatively prevents oxygen diffusion, and the second insulator includes an insulator material that relatively assists oxygen diffusion.

3. The memory device of claim 2, wherein the first insulator comprises at least one of silicon nitride, silicon oxynitride, or aluminum oxide.

4. The memory device of claim 2, wherein the second insulator comprises silicon oxide.

5. The memory device of claim 1, wherein an oxygen content in the channel region is higher than an oxygen content in the source region and the drain region.

6. The memory device of claim 1, wherein the channel region faces a corresponding word line among the plurality of word lines in the first direction, the source region contacts a corresponding bit line among the plurality of bit lines in the second direction, and the drain region contacts a corresponding capacitor among the capacitors in the second direction.

7. The memory device of claim 1, wherein each of the plurality of word lines comprises a first word line and a second word line arranged apart from each other in the first direction with a corresponding oxide semiconductor layer among the plurality of oxide semiconductor layers therebetween, the first word line and the second word line being parallel to each other and facing each other.

8. The memory device of claim 1, wherein, in a cross-section cut through the memory device in a plane perpendicular to the third direction,
a group of the plurality of oxide semiconductor layers connected to a corresponding bit line among the plurality of bit lines are arranged at intervals therebetween in the first direction, and
a width of each of the plurality of word lines in the second direction is less than a width of a corresponding one of the plurality of oxide semiconductor layers in the second direction.

9. The memory device of claim 8, wherein, in the cross-section, the first insulator fills respective spaces on both sides of the plurality of word lines in the second direction.

10. The memory device of claim 8, wherein, in the cross-section, the second insulator extends in the second direction and is between two adjacent ones of the plurality of oxide semiconductor layers in the first direction.

11. The memory device of claim 8, further comprising:
in the cross-section, a gate insulating film surrounding each of a lower surface and an upper surface of a corresponding one of the plurality of word lines and a second end side surface of the corresponding one of the plurality of word lines in the second direction.

12. The memory device of claim 11, wherein, in the cross-section, the gate insulating film is between the second end side surface of the corresponding one of the plurality of word lines in the second direction and the first insulator, and the first insulator is in direct contact with a first end side surface of the corresponding one of the plurality of word lines in the second direction.

13. The memory device of claim 11, wherein, in a cross-section of the memory device in which the channel region of each of the plurality of oxide semiconductor layers is cut along a plane perpendicular to the second direction,
the plurality of word lines extend in the third direction, and
the gate insulating film is in contact with each of the upper surface and the lower surface of a corresponding one of the plurality of word lines and extends in the third direction.

14. The memory device of claim 13, wherein
the gate insulating film includes a plurality of gate insulating films, and
in the cross-section, each of the plurality of oxide semiconductor layers is between two adjacent gate insulating films, that are adjacent to each other in the first direction, from among the plurality of gate insulating films.

15. The memory device of claim 14, wherein, in the cross-section,
the second insulator is on both sides of a corresponding one of the plurality of oxide semiconductor layers in the third direction, on a same layer as the corresponding one of the plurality of oxide semiconductor layers, and
an upper surface and a lower surface of the second insulator are in contact with the gate insulating film.

16. The memory device of claim 1, wherein, in a cross-section of the memory device in which the source region or the drain region of each of the plurality of oxide semiconductor layers is cut along a plane perpendicular to the second direction,
the source region or the drain region of each of the plurality of oxide semiconductor layers is completely surrounded by the first insulator.

17. The memory device of claim 16, further comprising:
the second insulator spaced apart from the plurality of oxide semiconductor layers and between two adjacent ones of the plurality of oxide semiconductor layers in the first direction, in the cross-section.

18. The memory device of claim 17, wherein, in the cross-section, a width of the second insulator in the third direction is equal to a width of a corresponding one of the plurality of oxide semiconductor layers in the third direction.

19. The memory device of claim 18, wherein, in the cross-section, the second insulator is completely surrounded by the first insulator.

20. An electronic apparatus comprising:
a memory device; and
a memory controller configured to control the memory device to read data from the memory device or write data to the memory device,
wherein the memory device comprises,
a plurality of bit lines extending in a first direction,
a plurality of oxide semiconductor layers extending in a second direction intersecting the first direction and connected to the plurality of bit lines, each of the plurality of oxide semiconductor layers comprising a source region, a drain region, and a channel region between the source region and the drain region,
a plurality of capacitors electrically connected to the plurality of oxide semiconductor layers, respectively,
a plurality of word lines extending in a third direction to intersect the plurality of oxide semiconductor layers, the third direction intersecting the first direction and the second direction,
a first insulator on each of both sides of the source region and the drain region in the third direction, and
a second insulator on each of both sides of the channel region in the third direction, the second insulator being different from the first insulator.
